(19) United States
(12) Patent Application Publication
(10) Pub. No.: US 2009/0108462 A1
(43) Pub. Date: Apr. 30, 2009

(54) DUAL INTEGRATION SCHEME FOR LOW RESISTANCE METAL LAYERS

(76) Inventors: Carsten Peters, Dresden (DE); Frank Feustel, Dresden (DE); Kai Frohberg, Niederau (DE)

Correspondence Address: WILLIAMS, MORGAN & AMERSON, 10333 RICHMOND, SUITE 1100, HOUSTON, TX, 77042, US

(21) Appl. No.: 12/104,692

(22) Filed: Apr. 17, 2008

(30) Foreign Application Priority Data
Oct. 31, 2007 (DE) 10 2007 052 048.6

(51) Int. Cl. H01L 23/48; H01L 21/4763

(52) U.S. Cl. 257/774; 438/637; 257/E23.01; 257/E21.495

(57) ABSTRACT

By forming a metal line extending through the entire interlayer dielectric material in resistance sensitive metallization layers, enhanced uniformity of these metallization layers may be obtained. The patterning of respective via openings may be accomplished on the basis of a recess formed in a cap layer, which additionally acts as an efficient etch stop layer during the patterning of the trenches, which extend through the entire interlayer dielectric material. Consequently, for a given design width of metal lines in resistance sensitive metallization layers, a maximum cross-sectional area may be obtained for the metal line with a high degree of process uniformity irrespective of a variation of the via density.

### BACKGROUND OF THE INVENTION

1. Field of the Invention

Generally, the subject matter disclosed herein relates to the formation of integrated circuits, and, more particularly, to forming metallization layers or metal layers in a dual inlaid integration regime for advanced integrated semiconductor devices.

2. Description of the Related Art

In modern integrated circuits, minimum feature sizes, such as the channel length of field effect transistors, have reached the deep sub-micron range, thereby steadily increasing performance of these devices in terms of speed and/or power consumption. As the size of the individual circuit elements is significantly reduced, thereby improving, for example, the switching speed of the transistor elements, the available floor space for interconnect lines electrically connecting the individual circuit elements is also decreased. Consequently, the dimensions of these interconnect lines have to be reduced to compensate for a reduced amount of available floor space and for an increased number of circuit elements provided per chip, thereby typically requiring a plurality of stacked wiring levels or metallization layers to accommodate the required number of interconnect structures. The wiring levels typically comprise metal lines, which are connected to metal regions and metal lines of adjacent metallization layers of the wiring layer stack by vertical contacts, also referred to as vias.

In advanced integrated circuits, a limiting factor of device performance may be the signal propagation delay caused by the switching speed of the transistor elements and the electrical performance of the wiring levels of the devices, which may be determined by the resistivity (R) of the metal lines and parasitic capacitance (C) that may depend on spacing of the interconnect lines, since the line-to-line capacitance is increased in combination, while a reduced conductivity of the lines may result from their reduced cross-sectional area. While, in some metallization levels, the RC time constants are the predominant factor that determines the overall performance, in other levels, a high series resistance of the metal lines, due to design restriction in view of the line width, may result in high current densities, which may lead to degraded performance and reduced reliability due to increased electromigration, i.e., a current induced material flow caused by high current densities.

Traditionally, metallization layers are formed by a dielectric layer stack including, for example, silicon dioxide and/or silicon nitride, with aluminum as the typical metal. Since aluminum exhibits significant electromigration at higher current densities than may be necessary in integrated circuits having extremely scaled feature sizes, aluminum is being replaced by copper or copper alloys, which have a significantly lower electrical resistance and a higher resistivity against electromigration. Moreover, a further decrease of the parasitic RC time constants may be achieved by replacing the well-established and well-known dielectric materials silicon dioxide (k≈4.2) and silicon nitride (k>5) by so-called low-k dielectric materials. However, the transition from the well-known and well-established aluminum/silicon dioxide metallization layer to a low-k dielectric/copper metallization layer is associated with a plurality of issues to be dealt with.

For example, copper and alloys thereof may not be deposited in relatively high amounts in an efficient manner by well-established deposition methods, such as chemical and physical vapor deposition. Moreover, copper may not be efficiently patterned by well-established anisotropic etch processes. Therefore, the so-called damascene or inlaid technique is frequently employed in forming metallization layers including copper-based lines. Typically, in the damascene technique, the dielectric layer is deposited and then patterned with trenches and vias that are subsequently filled with copper by plating methods, such as electroplating or electroless plating. In many damascene strategies, the openings for the vias and the metal lines are formed first and the metal is subsequently filled in during a common deposition process.

One well-established approach in this respect is the so-called “via first/trench last” approach, in which openings for the vias are formed first in the interlayer dielectric material and subsequently the trench openings are patterned, which may provide certain advantages, with respect to the process uniformity, compared to a “trench first/via last” approach, in which the trenches are formed first and thereafter the via openings are provided on the basis of sophisticated lithography and etch techniques. During the “via first/trench last” approach, the surface topography resulting from the patterning of the interlayer dielectric material may be planarized prior to actually patterning the trench openings on the basis of an appropriate material, such as a polymer material, a photoresist material and the like. However, in advanced semiconductor devices, the performance of the wiring level, i.e., the plurality of metallization layers, has to meet strict margins in order to provide the desired electrical behavior of the device under consideration. As previously explained, the various metallization levels may comprise metal lines and an interlayer dielectric material, wherein the line resistance and the permittivity of the dielectric material may substantially determine the overall electrical performance with respect to signal propagation, while other aspects, such as electromigration, reliability of the metal lines and the like, may also significantly depend on material composition, manufacturing processes and the like. In advanced semiconductor devices, it may be distinguished between metallization levels in which the capacitive behavior sensitively affects the overall performance, while in other metallization levels, a reduced overall resistance may contribute to enhanced device performance. Consequently, it may become increasingly important to specifically adjust electrical characteristics of certain metallization levels in view of their capacitive or resistive behavior. For example, for a metallization level requiring a reduced overall resistance of the metal lines formed therein, the cross-section of the metal lines should be increased, which may be accomplished by appropriately selecting the thickness of the interlayer dielectric material, in which the trenches and via openings are to be formed. It appears, however, that in sophisticated “via first/trench last” approaches, a significant non-uniformity of the respective metal thickness may be observed, as will be described in more detail with reference to FIGS. 1a-1b.

FIG. 1a schematically illustrates a cross-sectional view of a semiconductor device 100 comprising a substrate 101, such as a silicon-based material and the like. It should be appreciated that the substrate 101 may include a respective device layer, in which a plurality of circuit elements may be formed, such as transistors, capacitors and the like. As mentioned above, the plurality of circuit elements may require an appropriate connection according to the specified circuit layout, which may require a plurality of metallization layers 120, 140, which are provided in a stacked configuration. That is, the metallization layer 120, which may represent any arbitrary metallization layer, below which additional metallization layers (not shown) may be provided, typically comprises an interlayer dielectric material 121, which may include a low-k dielectric material, conventional dielectrics such as silicon dioxide, silicon nitride, silicon oxynitride and the like. Furthermore, the metallization layer 120 may comprise a plurality of metal lines, of which only one metal line 122 is illustrated in FIG. 1a. Furthermore, the metallization layer 140 may comprise, in the manufacturing stage shown, a dielectric material 141 comprised of any appropriate material composition, and may further include a plurality of via openings 143A, 143B. In FIG. 1a, the semiconductor device 100 may comprise, at least in the metallization layer 140, different device areas 102A, 102B and 102C which may correspond to areas in which a significantly different “density” of via openings 143A, 143B in the metallization layer 140 may exist. For example, the device area 102A may correspond to a region in which substantially no via is formed to the underlying metallization layer 120. Similarly, the device area 102B may represent a region with a moderately low via density, i.e., the via opening 143A may be considered as an isolated via opening. The device region 102C, on the other hand, may represent an area of high via density so as to connect the lower lying metallization layer 120, for instance, to one or more of the metal lines 122. It should be appreciated that the via openings 143B may not necessarily connect to the same metal line 122 as shown in FIG. 1a, but may connect to two or more metal lines, which are not shown in FIG. 1a.

Moreover, in the manufacturing stage as shown in FIG. 1a, the semiconductor device 100 may comprise a planarization material 144, which may be provided in the form of any appropriate material, such as a polymer material, a resist material and the like. For example, the material 144 may be provided to fill the via openings 143A, 143B and also provide an overall “planar” surface topography. It appears, however, that the effective thickness of the material 144 may significantly depend on via density in the respective device area, wherein typically the thickness of the material 144 may become smaller with an increasing via density. As shown, a thickness T₁ of the area 102A may be greater than a thickness T₂ of the area 102B, which, in turn, may be greater than a thickness T₃ of the area 102C having the highest via density.

The semiconductor device 100 as shown in FIG. 1a may be formed in accordance with well-established conventional process strategies including a manufacturing process for forming any circuit elements in the device layer included in the substrate 101, followed by the formation of one or more metallization layers, such as the layers 120 and 140. A respective manufacturing sequence using the “via first/trench last” approach will now be described with reference to the metallization layer 140, wherein it should be appreciated that the same process strategy may also be applied for forming the metallization layer 120. Thus, after forming the metallization layer 120 comprising the dielectric material 121, the metal line 122 and a cap layer 125, which, in sophisticated applications, is typically comprised of an etch stop and barrier material of moderately low permittivity, also referred to as BLok (bottom low-k) material, the dielectric material 141 of the layer 140 may be formed, for instance, by deposition, spin-on techniques and the like. Thereafter, advanced lithography and etch techniques may be used to provide a resist mask, possibly in combination with a hard mask material, if required, to define the lateral position and size of the via openings 143A, 143B in accordance with device requirements. Thereafter, the dielectric layer 141 may be etched in accordance with well-established anisotropic etch techniques, wherein typically the etch process may stop on and in the cap layer 125. Next, the planarization material 144 may be deposited, for instance, by highly non-conformal techniques, such as spin-on processes and the like, when the planarization material 144 may be provided in a low-viscous state, thereby filling the openings 143A, 143B and also providing a certain amount of excess material on horizontal device portions. Due to the different surface topography caused by the varying via density, the deposition of the material 144 may result in the different thicknesses T₁, T₂, T₃, as previously explained.

Thus, for a given thickness of the interlayer dielectric material 141, an average etch depth may be determined to comply with the various requirements, i.e., providing a required minimum thickness of the interlayer dielectric material 141 below a respective metal line for obtaining acceptable capacitance values, while also providing a required minimum conductivity of the metal lines to be formed in the material 141, while a lateral size or width and a distance of metal lines, i.e., in the region 102C, is determined by the design rules. Consequently, when forming a respective etch mask for defining trenches for the metal lines in the metallization layer 140, a varying thickness of the material 144 may be encountered, which may also affect the subsequent etch process. Thus, the effective etch depth in the various areas 102A, 102B, 102C may also vary, thereby providing a different metal thickness and thus cross-section area of the metal lines in these regions.

FIG. 1b schematically illustrates the semiconductor device 100 after completing the above-described sequence for patterning respective trenches and filling the same with a conductive material, such as copper, possibly in combination with an appropriate barrier material. Thus, respective metal lines 142A, 142B and 142C may be formed in the areas 102A, 102B, 102C, respectively, wherein a thickness 142T thereof may vary between the areas 102A 102B, 102C. Thus, according to conventional “via first/trench last” approaches, the resistivity of the metal lines 142A, 142B, 142C may differ, which may result in a performance non-uniformity, in particular when metallization layers are considered, in which the overall resistance of the respective metal lines may have a significant influence on the overall device performance.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein contemplates an enhanced patterning regime and respective semiconductor devices in which the metallization level may be formed by using an inlaid strategy, while also taking into consideration whether a respective metallization layer is a resistance sensitive layer or not. In the case of a resistance sensitive layer, the etch depth in the corresponding dielectric material may be increased, thereby efficiently increasing the cross-sectional area of the respective metal lines, which directly translates into a reduced line resistance. Furthermore, a uniform etch depth may be achieved by etching the trench opening through the entire interlayer dielectric material after the patterning of the respective via openings, wherein a specific material layer of the underlying metallization level may be used as an efficient etch stop material. For instance, a dielectric cap layer, which may frequently be used to confine sensitive metal regions, may be used as an efficient etch stop material, thereby providing a substantially uniform etch depth of the trenches, irrespective of the corresponding via density of the associated device area. Thus, the overall resistance of the metal lines may be decreased, while also enhancing the performance uniformity thereof.

One illustrative method disclosed herein comprises forming a recess in a cap layer of a first metallization layer of a semiconductor device, wherein the recess corresponds to a via to be formed such that it connects to a first metal region of the first metallization layer. The method further comprises forming an interlayer dielectric material above the cap layer and forming a first trench and a second trench in the interlayer dielectric material by using the cap layer as an etch stop material, wherein the first trench comprises the recess previously formed. Furthermore, the method comprises performing an etch process for opening the recess to form a via opening connecting to the first metal region and filling the via opening and the first and second trenches with a conductive material to form a second metallization layer.

A further illustrative method disclosed herein comprises forming above a first metallization layer an interlayer dielectric material of a second metallization layer. The method additionally comprises forming a via opening in the interlayer dielectric material and forming a recess in a cap layer of the first metallization layer, wherein the recess corresponds to the via opening. Furthermore, the method comprises forming a first trench and a second trench in the interlayer dielectric material, wherein the first and second trenches extend to the cap layer and wherein the first trench comprises the via opening. Furthermore, the via opening is deepened to extend through the cap layer and the via opening and the first and second trenches are filled with a conductive material to form a first metal line and a second metal line in the second metallization layer.

One illustrative semiconductor device disclosed herein comprises a device layer and a first metallization layer comprising a metal region. Furthermore, a second metallization layer is provided and comprises an interlayer dielectric material that is formed above a cap layer, wherein the cap layer confines the metal region. The semiconductor device further comprises a first metal line formed in the interlayer dielectric material, which extends to the cap layer. Finally, the semiconductor device comprises a via formed in the cap layer that connects the first metal line with the first metal region in the first metallization layer.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a semiconductor device during various manufacturing stages for forming a metallization layer according to a conventional “via first/trench last” approach;

FIGS. 2a-2f schematically illustrate cross-sectional views of a semiconductor device during various manufacturing stages for forming a metallization layer by forming a recess in a cap layer corresponding to a via opening and subsequently patterning trenches extending to the cap layer according to illustrative embodiments;

FIGS. 3a-3f schematically illustrate cross-sectional views of a semiconductor device during various manufacturing stages for forming a metallization layer, wherein trenches are etched down to a cap layer after the patterning of respective via openings, according to still further illustrative embodiments;

FIG. 3g schematically illustrates a cross-sectional view of a semiconductor device during a manufacturing process for forming a cap layer comprising an intermediate etch stop layer according to further illustrative embodiments; and

FIG. 3h schematically illustrates a semiconductor device comprising a plurality of metallization layers, wherein at least one of the metallization layers includes metal lines that extend down to a cap layer formed above a lower-lying metallization layer, according to still further illustrative embodiments.

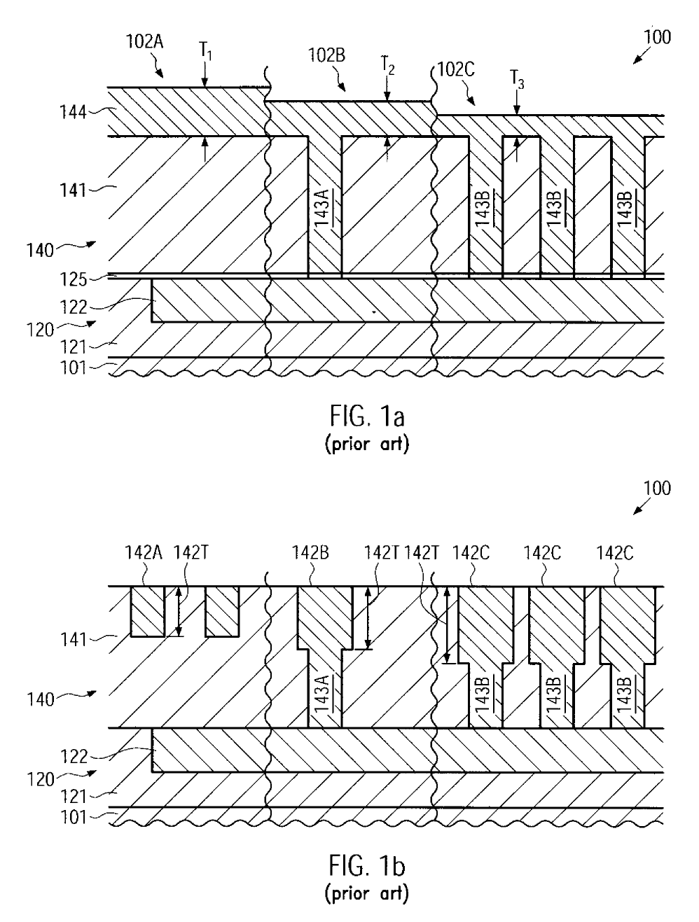

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure contemplates manufacturing techniques and semiconductor devices in which the performance of resistance sensitive metallization layers may be enhanced by providing improved etch uniformity and also increasing the total cross-sectional area of metal lines in the resistance sensitive metallization layer. For this purpose, the lateral position of via openings may be defined on the basis of a patterning process, wherein, in some illustrative aspects, a recess may be formed in a cap layer of a lower-lying metallization layer prior to actually providing the interlayer dielectric material for the subsequent metallization level. In a subsequent process sequence, the trenches may be patterned on the basis of photolithography and etch techniques, wherein the etch process may be controlled on the basis of the cap layer, which may therefore be used as an etch stop material. Consequently, the resulting trenches may have a substantially uniform depth, depending on the overall planarity of the interlayer dielectric material, while also providing a maximum cross-sectional area of the metal lines that have to be formed by filling the previously etched trenches. Due to the previously-defined recesses in the cap layer, via openings may be formed by etching through the cap layer within the recessed areas, while non-recessed cap layer portions and the respective trench bottoms may be maintained, however, at a reduced thickness so as to reliably avoid exposure of any underlying portions of the lower metallization level.

In other illustrative aspects disclosed herein, the interlayer dielectric material may be formed on the basis of a required target thickness and may subsequently be patterned so as to create via openings, which extend into the cap layer, thereby forming a recess therein. Thereafter, the trenches may be patterned, while also using the cap layer as an efficient etch stop material. As described before, also in this case, the previously-defined recesses corresponding to the via openings may be used in a subsequent etch step to provide via openings extending into the lower-lying metallization level, while the cap layer at non-recessed bottom portions of the trenches may reliably avoid exposure of the lower-lying materials. Consequently, for a given design width of metal lines, the techniques disclosed herein enable the formation of metal lines providing a maximum cross-sectional area for a given design width and a thickness of the interlayer dielectric material. Furthermore, a high degree of process uniformity may be obtained during the patterning of the trenches, irrespective of the via density in the corresponding device areas. Since the maximum cross-sectional area of the metal lines under consideration may be adjusted on the basis of a thickness of the interlayer dielectric material, the desired performance in terms of conductivity of resistance sensitive metallization layers may be adjusted by selecting an appropriate target value for the thickness of the interlayer dielectric material. Thus, the desired cross-sectional area may be readily adjusted on the basis of a deposition technique, without inducing etch-related non-uniformity.

The principles disclosed herein may be highly advantageous in the context of advanced semiconductor devices requiring complex metallization levels, in which capacitance sensitive and resistance sensitive layers may be included, which may be the case for a plurality of sophisticated integrated circuits, such as CPUs including extended memory areas, ASICs (application-specific ICs) and the like, which may comprise circuit elements, such as field effect transistors, which may be provided with high packing density in the device level. The critical dimensions of the respective circuit elements, such as the gate length of planar field effect transistors, may be 50 nm and less, thereby also requiring a reduced design width in the metallization levels. It should be appreciated, however, that the subject matter disclosed herein may also be advantageously applied to any microstructure devices and semiconductor devices requiring a plurality of metallization levels, wherein less critical design rules may be used. Hence, the present disclosure should not be considered as being restricted to specific device dimensions, unless such restrictions are specifically set forth in the specification or the appended claims.

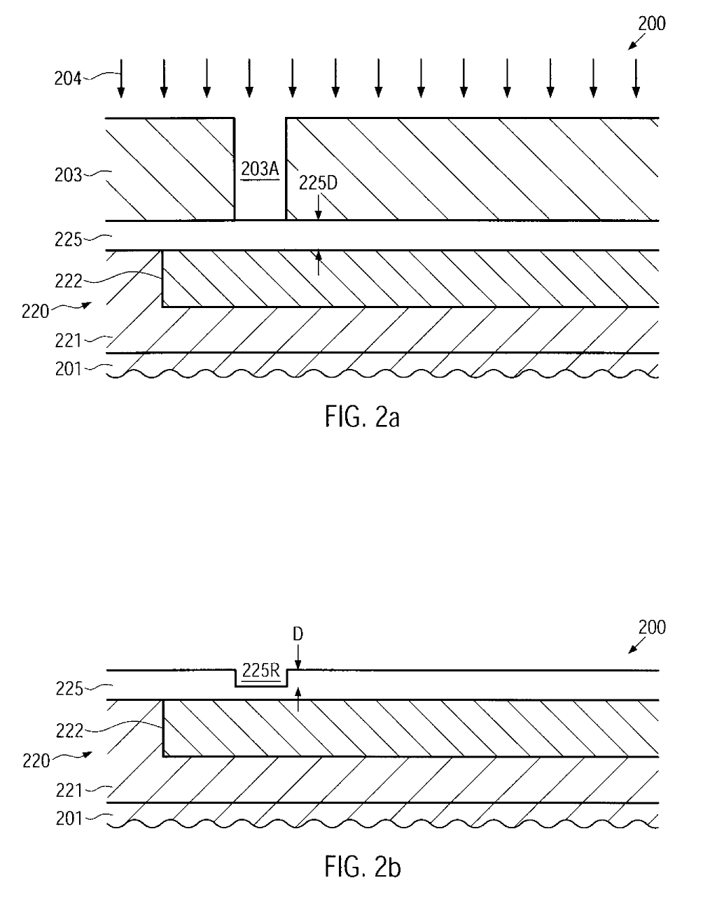

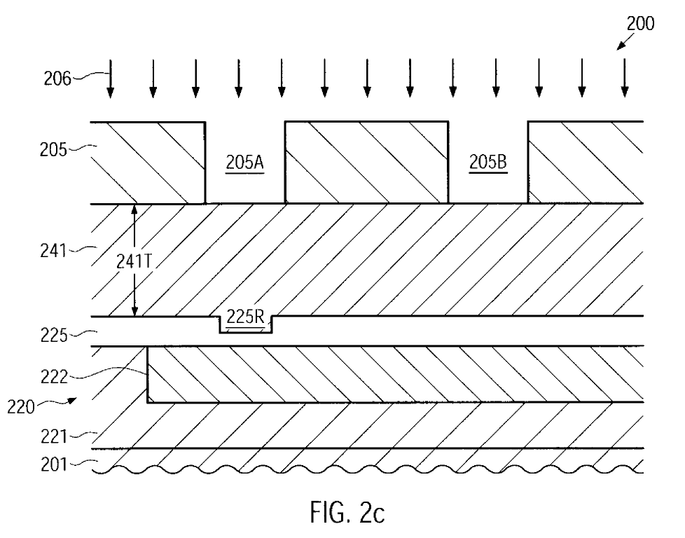

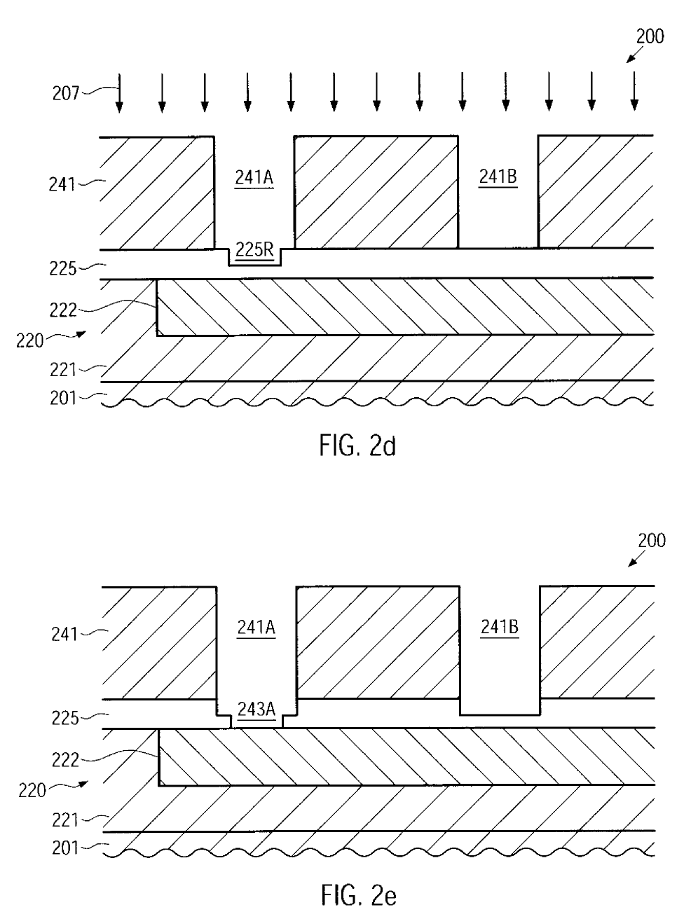

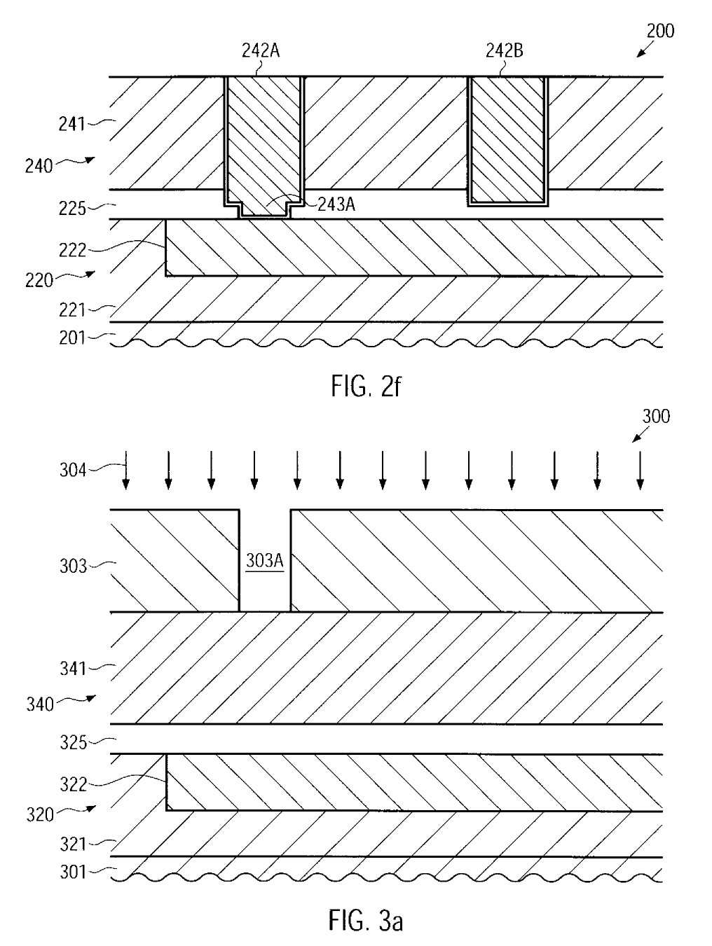

FIG. 2a schematically illustrates a cross-sectional view of a semiconductor device 200 comprising a substrate 201 and a metallization layer 220 formed above the substrate 201. The substrate 201 may represent any appropriate carrier material for forming therein and thereabove respective circuit elements, such as transistors, capacitors and the like. For example, the substrate 201 may comprise a silicon-based material, an upper portion of which may represent a semiconductor layer for forming therein and thereabove semiconductor elements, as required by the circuit layout under consideration. In other cases, the substrate 201 may represent an insulating material, in combination with an appropriate semiconductor layer, thereby establishing an SOI-like (semiconductor-on-insulator) configuration, wherein the SOI-like configuration, however, may be provided only partially across the substrate 201, depending on the specific requirements for the circuit elements under consideration. For convenience, any such circuit elements are not shown in FIG. 2a.

The metallization layer 220 may represent the first metallization layer in the sense that the layer 220 is the first wiring level of the device 200 above the device layer, wherein respective vertical contacts (not shown) may establish an electrical connection to one or more metal lines 222, which may be formed within a dielectric material 221 of the metallization layer 220. In other cases, the metallization layer 220 may represent any metallization level below and above which one or more metallization layers may be located. The dielectric material 221 of the layer 220 may be provided in the form of any suitable dielectric material, which may comprise, in sophisticated applications, a low-k dielectric material, wherein a relative permittivity of the low-k dielectric material may be 3.0 or less. Furthermore, the dielectric material 221 may be comprised of materials such as “conventional” dielectrics, such as silicon dioxide, silicon oxynitride, silicon nitride and the like. The metal line 222 may comprise as a main component a highly conductive metal, such as copper, copper alloys, silver, silver alloys, aluminum and the like, depending on the overall performance requirements for the metallization layer 220. In some illustrative embodiments, the metal line 222 may comprise a significant amount of copper. Furthermore, the metal line 222 may comprise an appropriate barrier material so as to confine the main component of the highly conductive metal in order to suppress undue out-diffusion of metal atoms into the surrounding dielectric material 221 and also to avoid undue interaction of reactive components, such as oxygen, fluorine and the like, which may diffuse from the dielectric material 221 towards the metal line 222. For convenience, any such barrier materials are not shown in FIG. 2a.

It should be appreciated that the metal line 222 may have a length direction, i.e., in FIG. 2a, the horizontal direction, and may also have a width direction, i.e., in FIG. 2a, a direction perpendicular to the drawing plane of FIG. 2a. In complex integrated circuits, respective metal lines, such as the metal line 222, may be formed such that these lines extend substantially in parallel, while metal lines of a vertically adjacent metallization layer may also substantially extend in parallel, however, perpendicular to the length direction of the metallization layer 220. In this context, any positional statements given herein should be considered as “relative” positional information, wherein the substrate 201 or a respective surface or interface thereof may act as a reference. Hence, a “vertical” direction may be considered as a direction of a surface normal of the substrate 201 while a “horizontal” direction may represent a lateral direction parallel to a respective surface or interface defined by the substrate 201. In this sense, the metallization layer 220 is formed “above” the substrate 201, and a cap layer 225, representing a portion of the metallization layer 220, is formed “above” the dielectric material 221 and the metal line 222.

The cap layer 225 may be comprised of any appropriate dielectric material, which, in some illustrative embodiments, may provide a reliable confinement of the metal line 222 while also acting as an efficient etch stop layer during the patterning of a dielectric material of a metallization layer to be formed above the layer 220. In some illustrative embodiments, the cap layer 225 may be comprised of a material having a moderately low permittivity, such as silicon carbide, nitrogen-containing silicon carbide, silicon dioxide, silicon oxynitride and the like. Depending on the overall performance of the metallization layers of the device 200, the cap layer 225 may also comprise silicon nitride, if a respective moderately high permittivity thereof is not considered inappropriate. In one illustrative embodiment, a thickness 225D of the cap layer 225 may be selected such that a recess may be reliably formed therein, which may be completely opened in a later stage during a respective etch process, while, in non-recessed areas, nevertheless, a reliable confinement of the underlying materials may be ensured, even when a respective material removal may occur during the etch process under consideration. For example, the thickness 225D may be selected to be approximately 15-50 nm for cap materials including silicon carbide, nitrogen-containing silicon carbide and the like. An appropriate target value for the thickness 225D may be readily established by examining the etch rate for a specific material composition with respect to an etch ambient, which is to be used in a later manufacturing stage for etching through the cap layer 225, as will be described later on in more detail. Furthermore, in the manufacturing stage as shown in FIG. 2a, an etch mask 203 may be provided, for instance, in the form of a resist mask, comprising an opening 203A, which may define the lateral position and the size of a corresponding via opening to be formed in the cap layer 225 so as to connect to the metal line 222.

The semiconductor device 200 as shown in FIG. 2a may be formed on the basis of the following processes. After manufacturing respective circuit elements (not shown), an appropriate contact structure may be formed in combination with a metallization level connecting to the contact structure. Thereafter, the metallization layer 220 may be formed, for instance, according to a “via first/trench last” approach, wherein it may be assumed that the layer 220 may represent a capacitance sensitive layer, in the sense that at least a certain thickness of the dielectric material 221 in the form of a low-k dielectric material may be required to provide a certain distance to any lower-lying metal lines (not shown). In other cases, the metallization layer 220 may be formed in accordance with other device requirements using any appropriate manufacturing regime. For example, the dielectric material 221 may be formed, for instance, by chemical vapor deposition (CVD), spin-on techniques and the like in any appropriate composition, wherein, in critical cases, an intermediate etch stop layer (not shown) or an intermediate etch indicator layer may be provided to efficiently control a respective etch process for patterning trenches in the dielectric material 221 with a specific target depth. It should be appreciated that respective vias (not shown) may be formed prior to or after the patterning of the trenches, wherein respective vias may also be formed in a separate manufacturing sequence and thereafter the metal lines 222 may be formed in a separate sequence, as is for instance the case for a single damascene strategy.

Thereafter, the cap layer 225 may be formed, for instance by plasma enhanced chemical vapor deposition (PECVD) with the appropriately selected thickness 225D so as to allow reliable patterning on the basis of the mask 203, while still acting as a reliable etch stop material in a subsequent process for patterning trenches for a next metallization level. It should be appreciated that the cap layer 225 may be comprised of two or more sub-layers, as will be described later on in more detail, to enhance the overall performance of the cap layer 225, for instance, in view of metal confinement, adhesion characteristics, electromigration performance, etch stop capabilities and the like. Next, the mask 203 may be formed, for instance, by advanced lithography, where, in the embodiment shown, less critical process conditions may be encountered, since a single resist mask may be sufficient for appropriately patterning the cap layer 225 to define therein a recess corresponding to the position and size of a via opening. Thereafter, the device 200 may be subjected to an etch process 204, which, in some illustrative embodiments, may be designed as a highly anisotropic process for removing a portion of the exposed part of the cap layer 225. For example, a plurality of plasma assist etch processes are well-established in the art for etching material which may be efficiently used as a cap layer in metallization levels. In other cases, the etch process 204 may even include a certain isotropic component, for instance, on the basis of a wet chemical etch chemistry, an isotropic dry etch process and the like, when a corresponding lateral increase of a respective recess in the cap layer 225 is acceptable or considered advantageous.

FIG. 2b schematically illustrates the semiconductor device 200 in an advanced manufacturing stage, after the above-described process sequence is completed and the etch mask 203 is removed. As shown, a recess 225R is provided in the cap layer 225 and thus defines the size and the position of a via opening for a metallization layer still to be formed. It should be appreciated that a depth D of the recess 225R may be adjusted on the basis of the process parameters of the etch process 204, for instance, for a given etch chemistry, the etch time may be selected so as to adjust the depth D. In some illustrative embodiments, the depth D is selected such that the remaining material below the recess 225R may provide sufficient etch stop capabilities in a subsequent trench patterning process in order to provide increased process manufacturing uniformity in a subsequent etch process for deepening the recess 225R to finally connect to the metal line 222, while, in other non-recessed portions, material of the cap layer 225 may be reliably maintained during the corresponding etch process. For example, the depth D may represent approximately one-half of the initial thickness 225D. As will be explained later on, in some embodiments, the depth D may be adjusted on the basis of an intermediate etch stop layer to further enhance the overall process uniformity.

FIG. 2c schematically illustrates the semiconductor device 200 in a further advanced manufacturing stage, in which a dielectric material 241, for instance, in the form of a low-k dielectric material or any other appropriate material, may be formed above the cap layer 225, followed by an etch mask 205 including respective openings 205A, 205B to define the lateral position and the size of trenches to be formed in the dielectric material 241. For example, the etch mask 205 may be provided in the form of a resist mask, possibly in combination with an anti-reflective coating (ARC) material (not shown) or any other hard mask material, if the etch resistivity of a resist mask may not be sufficient to entirely etch through the dielectric material 241.

The dielectric material 241 may be formed on the basis of any appropriate technique, such as CVD, spin-on and the like, or any combination thereof, wherein a thickness 241T thereof may be selected on the basis of a target value for the thickness of a metal line to be formed in the dielectric material 241. That is, as previously explained, for a resistance sensitive metallization layer, the cross-sectional area of a metal line may be increased for a given design width, as represented by the lateral size of the openings 205A, 205B. Hence, according to the principles disclosed herein, metal lines may extend through the entire thickness of the dielectric layer 241 so that the thickness thereof may be selected on the basis of the target thickness of the metal lines, thereby avoiding undue deposition of material of the layer 241 and also not unduly compromising the mechanical integrity of the resistance sensitive metallization layer under consideration.

After forming the dielectric material 241, the etch mask 205 may be formed on the basis of advanced lithography techniques for obtaining the openings 205A, 205B, which may have the same or a different width, depending on the design rules. Next, the device 200 is exposed to an anisotropic etch ambient 206 in order to pattern the dielectric material 241 on the basis of the etch mask 205. The etch process 206 may be controlled on the basis of the cap layer 225, which may act as an efficient etch stop material. In other illustrative embodiments, the cap layer 225 may have a reduced removal rate during the process 206, thereby significantly slowing down the material removal once material of the cap layer 225 is exposed by the process 206. Also, in this case, the previously formed recess 225R may thus result in an exposure of the metal line 222, while the overall reduced etch rate of the cap layer 225 may nevertheless provide sufficient process margins so as to reliably maintain a portion of the material 225 within respective openings formed on the basis of the mask openings 205A, 205B. That is, when the etch front reaches the cap layer 225, the reduction in overall removal rate may significantly slow down the further progression of the etch front, thereby efficiently “equalizing” across-substrate non-uniformities, while within the recess 225R, which may still be filled with material of the layer 241, a moderately high etch rate is still maintained, until material of the cap layer 225 is exposed. Thus, a significant delay of material removal of previously non-recessed portions with respect to the recess 225R may be further maintained during the progression of the etch process 206, thereby exposing the metal line 222 at an area corresponding to the recess 225R, while nevertheless reliably maintaining a certain amount of material of the cap layer 225 at initially non-recessed portions. Hence, in some illustrative embodiments, the etch process 206 may be performed as a single process etching through the material 241 and the cap layer 225 at the recess 225R, while maintaining other device portions covered by at least a portion of the cap layer 225.

FIG. 2d schematically illustrates the semiconductor device 200 according to other illustrative embodiments, in which the etch process 206 may be reliably stopped on the basis of the etch stop capabilities of the cap layer 225. Hence, a further etch process 207 may be performed on the basis of respective openings 241A, 241B, which may be obtained by the etch process 206 using the cap layer 225 as an etch stop. The etch process 207 may be designed to remove material of the cap layer 225 at an appropriate etch rate and to provide a required high etch controllability, while nevertheless not unduly contributing to the overall process time. For example, a plurality of plasma-assisted etch recipes are well-established in the art for materials that are typically used as dielectric barrier layers or cap layers in conventional dual damascene strategies.

FIG. 2e schematically illustrates the semiconductor device 200 after the etch process 207, thereby forming a via opening 243A connecting to the metal line 222, while reliably covering previously non-recessed portions, with a reduced thickness. Consequently, the dielectric material 241 may comprise the trenches 241A, 241B having a desired width in accordance with design rules and also having substantially the same depth substantially defined by the thickness of the dielectric layer 241 in combination with the material removal created during the etch process 207 and/or 206, as explained above. Consequently, the depth of the trenches 241A, 241B may be substantially equal, irrespective of the density of corresponding via openings connecting to the underlying metallization layer 220.

FIG. 2f schematically illustrates the semiconductor device 200 in a further advanced manufacturing stage, in which metal lines 242A, 242B are formed in the dielectric material 241, thereby defining a second metallization layer 240. Furthermore, the via 243A connects the metal line 242A with the metal line 222, while the metal line 242B may be separated and thus electrically insulated from the metal line 222 by the remaining portion of the cap layer 225. It should be appreciated that the metal lines 242A, 242B may have a maximum cross-sectional area for a given width thereof, thereby enhancing the overall performance of a resistance sensitive metallization layer. Furthermore, for identical line widths, a high degree of performance uniformity may be obtained for the metal lines 242A, 242B, irrespective of the via density in the various regions.

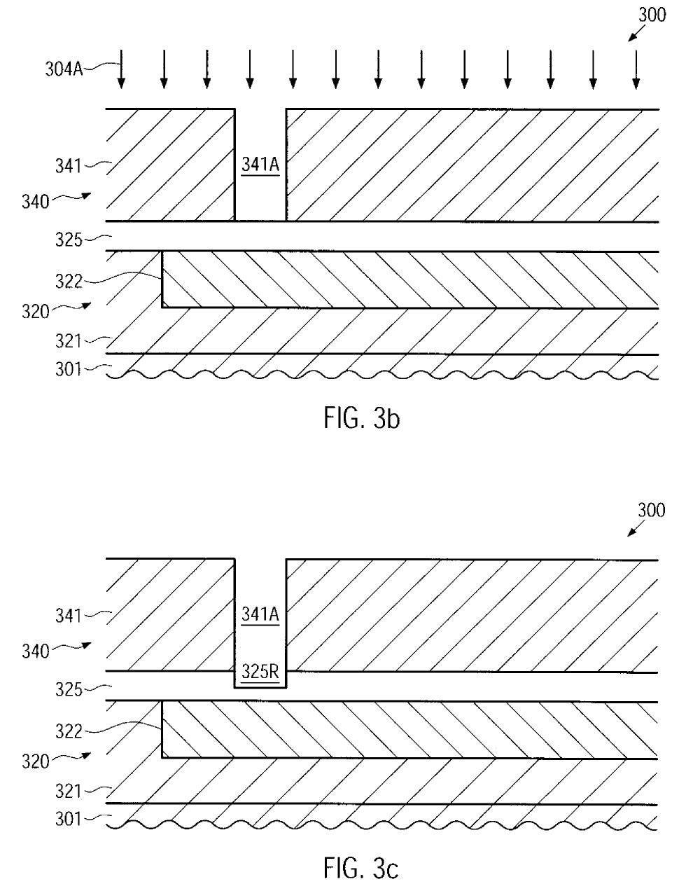

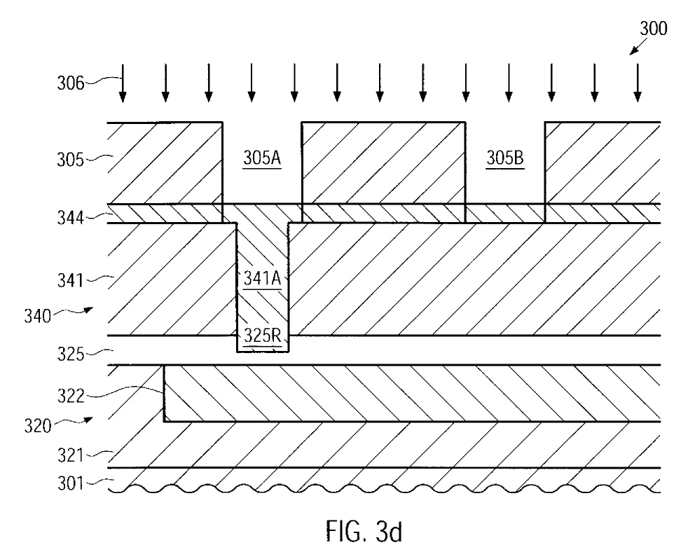

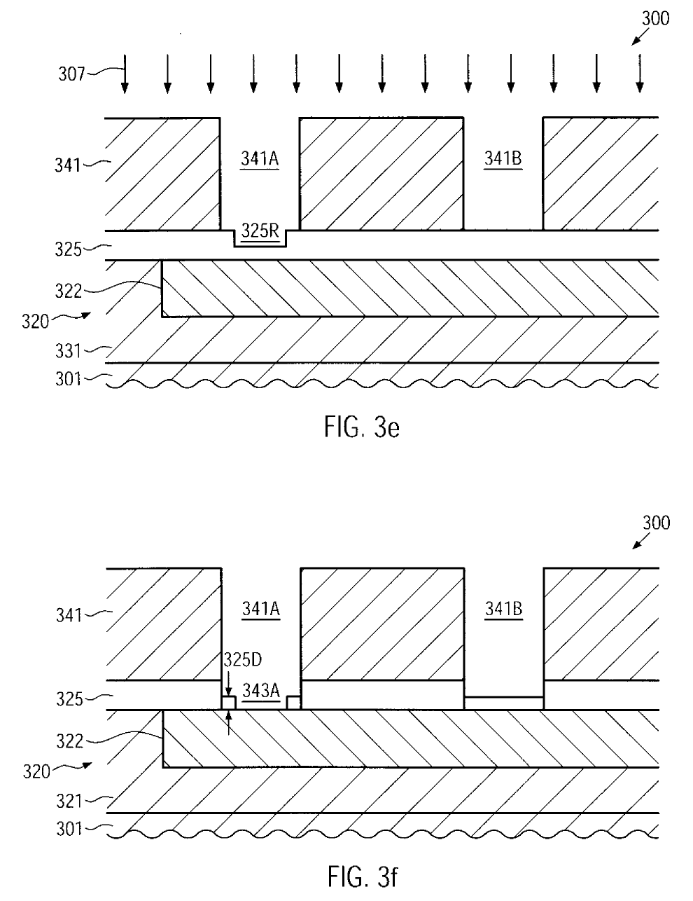

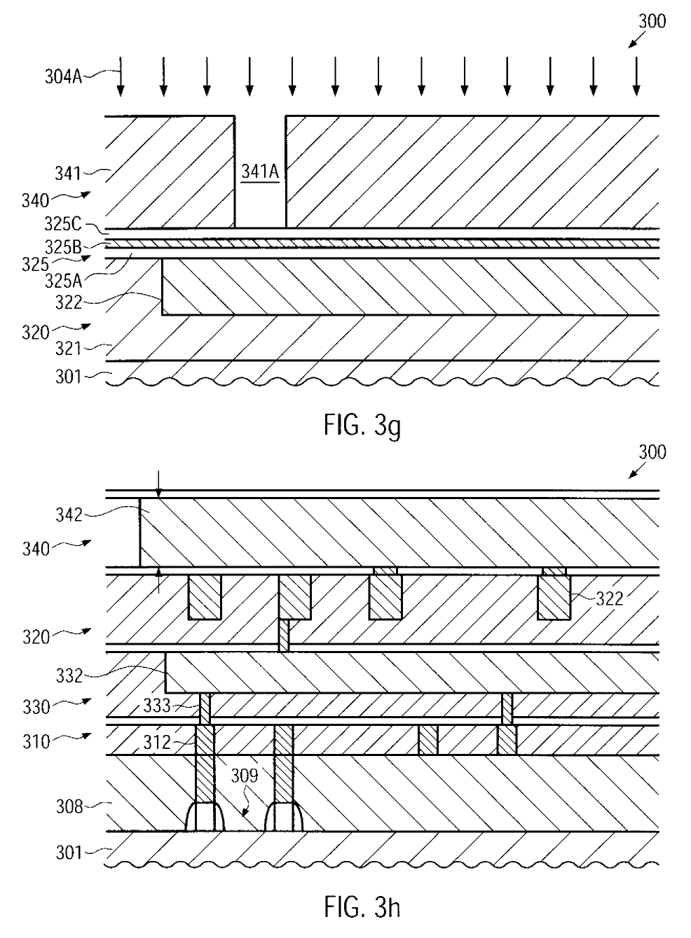

With reference to FIGS. 3a-3f, further illustrative embodiments will now be described in more detail, in which via openings may be patterned through a dielectric material so as to recess an underlying cap layer followed by the patterning of respective trenches, which may also completely extend through the dielectric material.

FIG. 3a schematically illustrates a semiconductor device 300 comprising a substrate 301 having formed thereabove a first metallization layer 320. The first metallization layer 320 may comprise a dielectric material 321 and a metal line 322 and a cap layer 325. Furthermore, a dielectric material 341 of a second metallization layer 340 may be formed above the first metallization layer 320. With respect to the components described so far, the same criteria apply as previously explained with reference to the semiconductor device 200. Furthermore, in the manufacturing stage shown, the semiconductor device 300 may further comprise an etch mask 303 including an opening 303A for defining the lateral position and the size of a via opening to be formed in the dielectric material 341. For instance, the etch mask 303 may be provided in the form of a resist mask, possibly in combination with ARC materials, hard mask materials and the like.

With respect to a manufacturing process for forming the device 300 as shown in FIG. 3a, the same criteria may apply as previously explained, wherein, contrary to the previously described embodiments, the dielectric material 341 of the metallization layer 340 may be formed on the cap layer 325 without recessing the same. Furthermore, the dielectric material 341 may be provided with an appropriate thickness so as to obtain the desired overall electrical performance of respective metal lines for a given design width, as previously explained. Thereafter, the mask 303 may be formed on the basis of advanced lithography techniques and subsequently an etch ambient 304 may be established to etch through the dielectric material 341 on the basis of the mask 303. For instance, efficient anisotropic etch recipes are well established in the art and may be used during the process 304. In one illustrative embodiment, the cap layer 325 may exhibit a high degree of etch resistivity with respect to the chemistry of the process 304, thereby acting as an efficient etch stop material.

FIG. 3b schematically illustrates the semiconductor device 300 during a further etch process 304A, which may represent a second etch step of the process 304, however, based on a different etch chemistry, while, in other illustrative embodiments, the etch process 304A may represent a final phase of the etch process 304, wherein the removal rate for the cap layer 325 may be sufficiently low to achieve a high degree of etch controllability for recessing the cap layer 325 in a controlled manner. In still other cases, the process 304A may be designed to remove residuals of the etch mask 303, while also recessing the cap layer 325, for instance, on the basis of a fluorine-containing etch chemistry within an oxygen-based plasma-assisted removal process. However, as previously described with reference to the process 204, any other appropriate etch chemistries may be used, wherein even isotropic etch steps may be employed, if a corresponding increase of the lateral dimensions may be considered appropriate.

FIG. 3c schematically illustrates the semiconductor device 300, after the etch process 304a, thereby obtaining a recess 325R in the cap layer 325.

FIG. 3d schematically illustrates the semiconductor device 300 in a further advanced manufacturing stage. As shown, a planarization material 344 may be provided, for instance, filling the via opening 341A and also providing a material layer above the dielectric material 341. For instance, the planarization material 344 may have similar characteristics to those previously described with reference to the semiconductor device 100 when describing the material 144. Furthermore, an etch mask 305 may be formed above the material 344 to define respective trenches 305A, 305B in order to define the lateral position and the size of metal lines to be formed in the metallization layer 340.

The planarization material 344 and the etch mask 305 may be formed on the basis of well-established process techniques, as, for instance, described with reference to the device 100. It should be appreciated that any difference in the thickness of the material 344 may not substantially negatively affect the efficiency of an etch process 306 designed to etch through the dielectric material 341 down to the cap layer 325. That is, due to the fact that the trenches may be formed through the entire dielectric material 341 using the cap layer 325 as an efficient etch stop material, any thickness non-uniformities obtained by the application of the planarization material 344, for instance due to different via densities, may be substantially avoided or at least significantly reduced.

FIG. 3e schematically illustrates the semiconductor device 300 after the etch process 307, thereby creating trenches 341A, 341B that extend down to the cap layer 325. Furthermore, the recess 325R may also be exposed by the previous etch process 306. Moreover, a further etch process 307 may be performed to deepen the recess 325R in order to form a via opening extending to the metal line 322. For this purpose, any appropriate process recipe may be used, wherein, in some illustrative embodiments, a fluorine-containing etch chemistry may be used, for instance, in combination with an oxygen-based plasma, thereby also efficiently removing any resist material of the etch mask 305. In this manner, an efficient yet highly controllable etch process may be obtained, thereby etching through the cap layer 325 on the basis of the recess 325R, while reliably maintaining a certain portion of the cap layer 325 in previously non-recessed areas within the trenches 341A, 341B.

FIG. 3f schematically illustrates the semiconductor device 300 after the end of the etch process 307, thereby resulting in a via opening 343A, while maintaining a portion of the cap layer 325 with reduced thickness 325D and reliably isolating the trenches 341A, 341B from underlying material of the metallization layer 320. Thereafter, the trenches 341A, 341B and the via opening 343A may be filled with a conductive material, for instance, a barrier material and a highly conductive metal, such as copper, to form metal lines in the trenches 341A, 341B and a metal-filled via 343A. Thereafter, an appropriate cap layer may be formed to complete the second metallization layer 340.

Similarly, as in the embodiments described with reference to FIGS. 2a-2f, an efficient manufacturing technique may be provided in which metal lines of the metallization layer 340 may extend through the entire dielectric material 341, thereby providing maximum conductivity for a given material composition and line width, irrespective of the via density in the various device regions of the metallization level under consideration.

FIG. 3g schematically illustrates a cross-sectional view of the semiconductor device 300 according to further illustrative embodiments, in which the cap layer 325 may be provided in the form of a plurality of sub-layers so as to enhance the overall performance thereof. It should be appreciated that the cap layer 325 as shown in FIG. 3g may be used in any of the embodiments described above. As shown, the cap layer 325 may comprise a plurality of sub-layers 325A, 325B, 325C. The sub-layers 325A, 325B, 325C may be designed to enhance the overall performance, for instance with respect to metal confinement, etch stop capabilities, compliance with other materials and the like. For instance, the sub-layer 325A may be provided to obtain reliable confinement of the metal line 322 and also to obtain high performance of the metal line 322, for instance in view of electromigration and the like. As is well known, an interface between the metal line 322 and the cap layer 325 may have a significant influence on the overall electromigration behavior, since typically surface irregularities, diffusion paths, grain boundaries and the like may influence the resistance against electromigration. Thus, the sub-layer 325A may be formed on the basis of respective criteria in order to obtain enhanced performance.

It should be appreciated that the sub-layer 325A may itself be comprised of two or more sub-layers, if considered appropriate. Furthermore, an etch control layer 325B may be provided, for instance in the form of an etch stop layer, which may provide enhanced etch stop capabilities when recessing the cap layer 325. For example, the etch control layer 325B may be comprised of a material having a high etch selectivity with respect to the layer 325C during a corresponding etch process, such as the etch process 304A, for recessing the cap layer 325. Thus, in this case, the depth of the resulting recess may be defined with high precision, irrespective of etch non-uniformities during the preceding etch process for patterning a dielectric material, such as the material 341, which may result in a certain degree of material erosion of the cap layer 325. In other cases, a respective etch process for patterning the cap layer 325 may be performed prior to forming the dielectric material 341, as is, for instance, shown in the embodiment of FIGS. 2a-2f, and also in this case the etch control layer 325B may enhance overall process controllability and uniformity. In other illustrative embodiments, the etch control layer 325B may comprise an etch indicator species, which may be liberated during a respective etch process, thereby providing a pronounced endpoint detection signal. For example, any appropriate species, even very exotic species, may be incorporated into the etch control layer 325B so as to obtain an efficient endpoint detection signal without unduly affecting the overall characteristics of the cap layer 325. For instance, the respective exotic species may be incorporated by an implantation after forming the cap layer 325, thereby suitably positioning the etch indicator species to define the sub-layers 325A, 325B, 325C. In other cases, the indicator material may be incorporated by plasma treatment after deposition of material corresponding to the layers 325A, 325B, followed by a further deposition to form the layer 325C. The layer 325C may be provided with an appropriate material composition to provide the desired etch stop capabilities while not unduly contributing to the overall permittivity of the cap layer 325. For instance, any appropriate material composition, including, for instance, silicon carbide, nitrogen-containing silicon carbide, silicon nitride, silicon dioxide and the like, may be used in order to appropriately adjust the overall performance of the cap layer 325.

Thereafter, the further processing may be continued, as is, for instance, described with reference to the semiconductor devices 200 and 300.

FIG. 3h schematically illustrates the semiconductor device 300 corresponding to the manufacturing stage in which a plurality of metallization layers are formed above a device layer 308, which may comprise a plurality of circuit elements 309. The circuit elements 309 may be connected to the first metallization layer 310, which may in turn be connected to a further metallization layer 330 by vias 333, wherein the metallization layer 330 may represent a capacitance sensitive layer, thereby requiring a minimum distance between metal lines 312 of the first metallization layer 310 and metallization lines 332 of the layer 330. Similarly, the metallization layer 320 may also represent a capacitance sensitive layer, thereby also requiring a minimum distance between the respective metal lines 322 and the metal lines 332 of the underlying metallization layer 330. On the other hand, the metallization layer 340 may represent a resistance sensitive layer, in which high conductivity for a given line width of the line 342 may provide overall performance gain of the device 300. Hence, the metal lines 342 may extend through the entire dielectric material 341, as previously explained, wherein a corresponding thickness of the layer 341 may be selected on the basis of the required cross-sectional areas of the metal lines 342, as previously discussed.

As a result, the subject matter disclosed herein provides enhanced semiconductor devices and manufacturing techniques for forming metallization levels in which, in resistance sensitive metallization layers, an increased cross-sectional area may be obtained for a given design width by forming the metal lines to extend through the entire interlayer dielectric material. Furthermore, the lateral position and size of respective vias connecting to a lower-lying metallization level may be defined prior to or after the deposition of the interlayer dielectric material, depending on the process strategy. The cap layer formed below the interlayer dielectric material may be efficiently recessed during the via patterning process, thereby providing sufficient process margins in order to reliably etch through the cap layer on the basis of the previously formed recess, while nevertheless providing reliable coverage of initially non-recessed portions of the cap layer.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a recess in a cap layer of a first metallization layer of a semiconductor device, said recess corresponding to a via to be formed so as to connect to a first metal region of said first metallization layer;
forming an interlayer dielectric material above said cap layer;
forming a first trench and a second trench in said interlayer dielectric material by using said cap layer as an etch stop material, said first trench comprising said recess;
performing an etch process for opening said recess to form a via opening connecting to said first metal region; and
filling said via opening and said first and second trenches with a conductive material to form a second metallization layer.

2. The method of claim 1, wherein said cap layer is provided with a thickness for avoiding exposure of said first metallization layer within said second trench when performing said etch process.

3. The method of claim 1, further comprising providing an etch stop sub-layer in said cap layer, wherein said recess is formed by using said etch stop sub-layer as an etch stop.

4. The method of claim 1, further comprising selecting a target thickness for metal regions in said second metallization layer and forming said interlayer dielectric material with a thickness corresponding to said target thickness.

5. The method of claim 1, further comprising forming a conductive cap layer on said first metal region, wherein said recess is formed to extend to said conductive cap layer.

6. The method of claim 1, further comprising forming at least a third metallization layer including vias and metal lines, wherein a thickness of said metal lines is less than a thickness of an interlayer dielectric material of said third metallization layer.

7. The method of claim 1, wherein a lateral size of said via opening is approximately 200 nm or less.

8. A method, comprising:
forming above a first metallization layer an interlayer dielectric material of a second metallization layer;
forming a via opening in said interlayer dielectric material;
forming a recess in a cap layer of said first metallization layer, said recess corresponding to said via opening;
forming a first trench and a second trench in said interlayer dielectric material, said first and second trenches extending to said cap layer and said first trench comprising said via opening;
deepening said via opening so as to extend through said cap layer; and
filling said via opening and said first and second trenches with a conductive material to form a first metal line and a second metal line.

9. The method of claim 8, wherein forming said first and second trenches comprises etching through said interlayer dielectric material and using said cap layer as an etch stop layer.

10. The method of claim 8, further comprising determining a target thickness for said first and second metal lines and forming said interlayer dielectric material with a layer thickness corresponding to said target thickness.

11. The method of claim 8, wherein deepening said via opening so as to extend through said cap layer comprises etching exposed material in said first and second trenches and using said recess as an etch mask.

12. The method of claim 8, further comprising providing an etch stop sub-layer in said cap layer and wherein forming said recess comprises controlling an etch process for forming said recess on the basis of said etch stop sub-layer.

13. The method of claim 12, wherein said first mask is formed so as to expose an area of said dielectric material corresponding to said opening and to cover the remaining portion of said dielectric material.

14. The method of claim 13, further comprising forming said cap layer by forming a first sub-layer for confining a metal region in said first metallization layer, forming said etch stop sub-layer and forming a second sub-layer as an etch stop layer when forming said first and second trenches.

15. The method of claim 13, wherein forming said first and second trenches comprises forming a resist mask and patterning said interlayer dielectric material using said resist mask.

16. The method of claim 15, further comprising forming a planarization layer above said interlayer dielectric material prior to forming said resist mask.

17. A semiconductor device, comprising:
a device layer;
a first metallization layer comprising a metal region;
a second metallization layer comprising an interlayer dielectric material formed above a cap layer, said cap layer confining said metal region;
a first metal line formed in said interlayer dielectric material and extending to said cap layer; and
a via formed in said cap layer and connecting said first metal line with said first metal region in said first metallization layer.

18. The semiconductor device of claim 17, wherein a portion of said cap layer separating said first metal line from said metal region of the first metallization layer has a first thickness and a portion of said cap layer laterally outside said first metal line has a second thickness that is greater than said first thickness.

19. The semiconductor device of claim 18, further comprising a second metal line formed in said interlayer dielectric material and extending to said cap layer, wherein a portion of said cap layer separating said second metal line from said first metallization layer has said first thickness.

20. The semiconductor device of claim 17, further comprising a third metallization layer comprising a third interlayer dielectric material and a third metal line formed therein, said third metal line vertically not extending through said third interlayer material.

21. The semiconductor device of claim 17, wherein said cap layer comprises an intermediate etch stop layer and wherein said first metal line extends to said intermediate etch stop layer.
